(19) United States
(12) Patent Application Publication
(10) Pub. No.: US 2015/0271923 A1
(43) Pub. Date: Sep. 24, 2015

(54) PRINTED WIRING BOARD AND METHOD FOR MANUFACTURING PRINTED WIRING BOARD

(71) Applicant: lBlDEN CO., LTD., Ogaki-shi (JP)

(72) Inventors: Toyotaka SHIMABE, Ogaki-shi (JP); Ryuichiro Tominaga, Ogaki-shi (JP)

(73) Assignee: IBIDEN CO., LTD., Ogaki-shi (JP)

(21) Appl. No.: 14/663,573

(22) Filed: Mar. 20, 2015

(30) Foreign Application Priority Data
Mar. 20, 2014 (JP) 2014-058127

(51) Int. Cl. H05K 1/18; H05K 3/46; H05K 1/02; H05K 3/00; H05K 1/03; H05K 1/11

(52) U.S. Cl. CPC H05K 1/185; H05K 1/032; H05K 1/116; H05K 1/0298; H05K 3/0058; H05K 3/46; H05K 3/4644; H05K 2201/096; H05K 2201/10015

(57) ABSTRACT

A printed wiring board includes a multilayer core substrate, an electronic component accommodated in an opening portion formed in the multilayer core substrate, and a build-up layer including an interlayer resin insulating layer formed on the multilayer core substrate such that the interlayer resin insulating layer is covering the opening portion of the multilayer core substrate. The multilayer core substrate includes resin layers, inner layer conductor patterns formed on an inner layer of the resin layers and outer layer conductor patterns formed on an outer layer of the resin layers, and via conductors formed in the resin layers, and the multilayer core substrate is formed such that a distance from the opening portion to each of the inner layer conductor patterns is greater than a distance from the opening portion to each of the outer layer conductor patterns.

### CROSS-REFERENCE TO RELATED APPLICATIONS

The present application is based upon and claims the benefit of priority to Japanese Patent Application No. 2014-058127, filed Mar. 20, 2014, the entire contents of which are incorporated herein by reference.

### BACKGROUND OF THE INVENTION

1. Field of the Invention

The present invention relates to a printed wiring board that has an electronic component built therein and to a method for manufacturing the printed wiring board.

2. Description of Background Art

Japanese Patent Laid-Open Publication No. 2007-288179 describes a printed wiring board in which a chip capacitor is built in a core substrate. The core substrate has a through-hole conductor that connects conductor circuits on front and back sides of the core substrate. The entire contents of this publication are incorporated herein by reference.

### SUMMARY OF THE INVENTION

According to one aspect of the present invention, a printed wiring board includes a multilayer core substrate, an electronic component accommodated in an opening portion formed in the multilayer core substrate, and a build-up layer including an interlayer resin insulating layer formed on the multilayer core substrate such that the interlayer resin insulating layer is covering the opening portion of the multilayer core substrate. The multilayer core substrate includes resin layers, inner layer conductor patterns formed on an inner layer of the resin layers and outer layer conductor patterns formed on an outer layer of the resin layers, and via conductors formed in the resin layers, and the multilayer core substrate is formed such that a distance from the opening portion to each of the inner layer conductor patterns is greater than a distance from the opening portion to each of the outer layer conductor patterns.

According to another aspect of the present invention, a method for manufacturing a printed wiring board includes forming a multilayer core substrate including outer layer conductor patterns including an alignment mark, applying laser upon the multilayer core substrate using the alignment mark as a reference such that an opening portion is formed at an opening formation position of the multilayer core substrate, accommodating an electronic component in the opening portion of the multilayer core substrate, and forming a build-up layer including an interlayer resin insulating layer on the multilayer core substrate such that the interlayer resin insulating layer covers the opening portion of the multilayer core substrate. The forming of the multilayer core substrate includes laminating resin layers, forming via conductors in the resin layers, forming inner layer conductor patterns on an inner layer of the resin layers, and forming outer layer conductor patterns on an outer layer of the resin layers, and the inner layer conductor patterns and the outer layer conductor patterns are formed such that a distance from the opening formation position to each of the inner layer conductor patterns is greater than a distanced from the opening formation position to each of the outer layer conductor patterns.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a cross-sectional view of a printed wiring board according to a first embodiment of the present invention;

FIGS. 2A and 2B illustrate cross-sectional views of a multilayer core substrate of the printed wiring board according to the first embodiment; FIGS. 3A, 3B, 3C1 and 3C2 illustrate explanatory diagrams of arrangements of an opening and conductor layers;

FIG. 4A-4E illustrate process diagrams illustrating a method for manufacturing the printed wiring board of the first embodiment;

FIG. 5A-5D illustrate process diagrams illustrating the method for manufacturing the printed wiring board of the first embodiment;

FIG. 6A-6D illustrate process diagrams illustrating the method for manufacturing the printed wiring board of the first embodiment;

FIG. 7A-7E illustrate process diagrams illustrating the method for manufacturing the printed wiring board of the first embodiment;

FIG. 8A-8D illustrate process diagrams illustrating the method for manufacturing the printed wiring board of the first embodiment;

FIGS. 9A and 9B illustrate process diagrams illustrating the method for manufacturing the printed wiring board of the first embodiment; and

FIG. 10 illustrates a cross-sectional view of a printed wiring board according to a modified example of the first embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

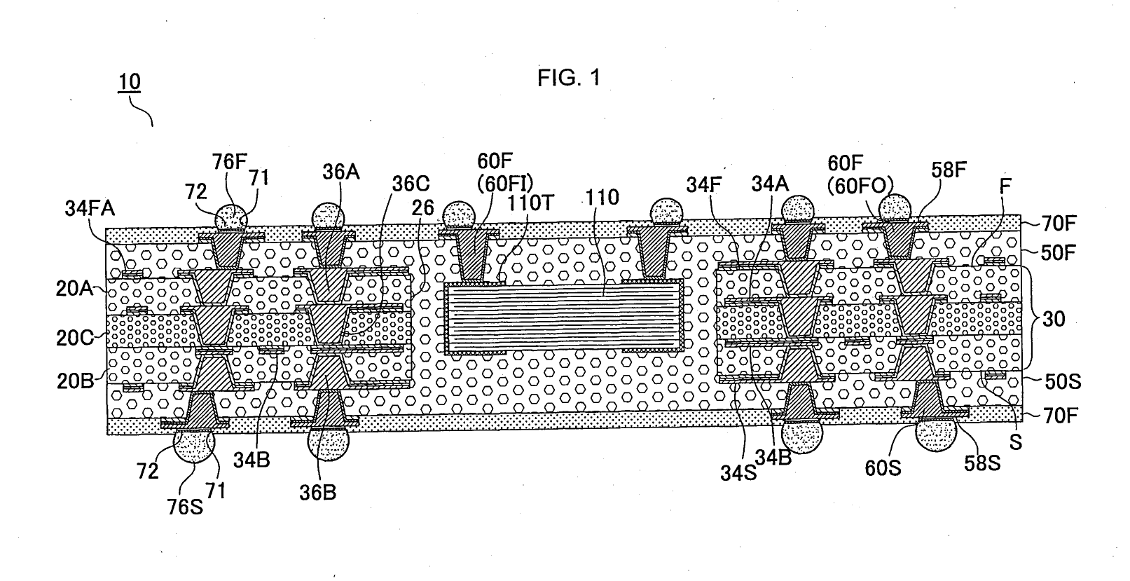

A cross section of a printed wiring board 10 according to a first embodiment of the present invention is illustrated in FIG. 1. In the printed wiring board 10, an electronic component 110 such as a chip capacitor is built in a multilayer core substrate 30 that has a first surface (F) and a second surface (S) that is on an opposite side of the first surface.

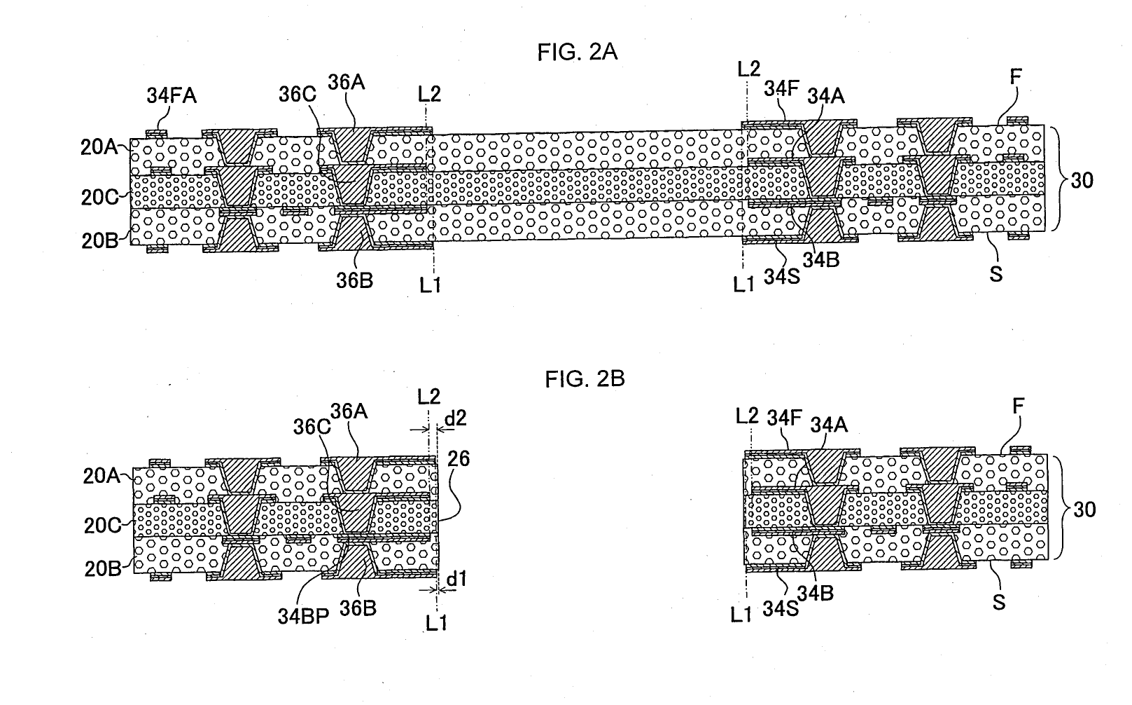

FIG. 2B illustrates a cross-sectional view of the multilayer core substrate. The multilayer core substrate 30 of the printed wiring board of the first embodiment has a third resin layer (20C), and has a first resin layer (20A) and a second resin layer (20B) that sandwich the third resin layer. The first resin layer is an uppermost layer of the core substrate, and the second resin layer is a lowermost layer of the core substrate. The first surface (F) of the core substrate and a first surface of each of the resin layers are the same surface side; and the second surface (S) of the core substrate and a second surface of each of the resin layers are the same surface side. The resin layers (20C, 20A, 20B) each have a reinforcing material. When the third resin layer has a thickness greater than that of the first resin layer and greater than that of the second resin layer, a thickness of the core substrate can be easily adjusted. The built-in electronic component and the core substrate have equal thicknesses. When the thicknesses of the resin layers are substantially the same, via conductors of the resin layers have equal lengths. Reliability of through-hole conductors is increased.

The core substrate has a first conductor layer (34F) on the first surface of the first resin layer, a second conductor layer (34S) on the second surface of the second resin layer, a third conductor layer (34A) between the first resin layer and the third resin layer, and a fourth conductor layer (34B) between the second resin layer and the third resin layer. The first, second and third conductor layers include via lands. The fourth conductor layer includes via pads (34BP) (pads of via conductors). The first, second, third and fourth conductor layers may further include conductor circuits.

The core substrate further has an interlayer connection conductor (via conductor) (36A) that penetrates through the first resin layer and connects the first conductor layer and the third conductor layer, an interlayer connection conductor (via conductor) (36B) that penetrates through the second resin layer and connects the second conductor layer and the fourth conductor layer, and an interlayer connection conductor (via conductor) (36C) that penetrates through the third resin layer and connects the third conductor layer and the fourth conductor layer.

The via conductors (36A, 36B, 36C) are linearly laminated. A through-hole conductor is formed by these via conductors and the via pad (34BP) sandwiched by the via conductor (36B) and the via conductor (36C). The via conductor (36A) is directly laminated on the via conductor (36C). The via conductor (36C) and the via conductor (36B) sandwich the via pad (34BP).

Further, the core substrate has an opening 26 that reaches from the first surface (F) to the second surface (S). The opening 26 penetrates through the resin layers that form the core substrate. The electronic component is accommodated in the opening.

In the first embodiment, outer layer conductor patterns (the first conductor layer (34F) and the second conductor layer (34S)) are formed on a line (L1) at a distance (d1) of 50 μm from the opening 26. Inner layer conductor patterns (the third conductor layer (34A) and the fourth conductor layer (34B)) are formed on a line (L2) at a distance (d2) of 70 μm from the opening 26. FIG. 3A illustrates a plan view illustrating the opening 26 and the lines (L1, L2). FIG. 3B illustrates a plan view illustrating an arrangement example of the outer layer conductor pattern (first conductor layer) (34F). In FIG. 3B, separated by the line (L1), a frame-shaped plane layer (34FP) surrounding an outer periphery of the opening 26 is formed. FIG. 3C1 illustrates a plan view illustrating an arrangement example of the outer layer conductor pattern (first conductor layer) (34F). In FIG. 3C1, separated by the line (L1), via lands (34FR) are arranged. The inner layer conductor pattern (third conductor layer) (34A) to which the via conductors (36A) of the via lands are connected is illustrated in FIG. 3C2. In the inner layer conductor pattern (third conductor layer) (34A), via lands (34AR) are formed in such a manner that a part of each of the via lands (34AR) on a side facing the opening 26 is cut off along the line (L2).

In the first embodiment, a distance from the opening 26 of the multilayer core substrate 30 to each of the inner layer conductor patterns (34A, 34B) is greater than a distance from the opening to each of the outer layer conductor patterns (34F, 34S) by 20 μm or more. Therefore, as illustrated in FIG. 2A, when the opening is formed in the multilayer core substrate using laser using an alignment mark (34FA) of the outer layer conductor pattern (34F) as a reference, the inner layer conductor patterns (34A, 34B) are avoided from being hit by the laser. The opening for accommodating the electronic component can be properly formed. Therefore, reliability of the printed wiring board with the built-in electronic component is enhanced.

In the first embodiment, the core substrate having the opening 26 for accommodating the electronic component is formed by the resin layers. In FIG. 1 of Japanese Patent Laid-Open Publication No. 2007-288179, a through hole for a through-hole conductor is formed in a single-sheet core substrate. In contrast, in the present embodiment, the core substrate is formed by the resin layers, and an opening for a via conductor is formed in each of the resin layers. Therefore, as compared to the case where the through hole for the through-hole conductor is formed in the single-sheet core substrate, in the first embodiment, the openings for the via conductors each have a shallower depth. Therefore, the openings for the via conductors can each have a smaller diameter. In the first embodiment, a pitch between the through-hole conductors can be narrowed.

By using the resin layers to form the core substrate, the resin layers each have a thinner thickness. Therefore, the openings for the via conductors that are formed in the respective resin layers can be easily filled by plating. Via conductors containing fewer defects such as voids or containing no defects are formed. Therefore, the through-hole conductor has a lower resistance.

The core substrate of the first embodiment has the opening for accommodating the electronic component. Therefore, the core substrate has a low strength. However, in the first embodiment, the through-hole conductor is formed by a via pad that is formed from a filled via and metal. Therefore, the core substrate has a high strength. Therefore, even when the core substrate has the opening for accommodating the electronic component, the printed wiring board has a small warpage. The electronic component that is built in the core substrate is unlikely to be damaged. Even when the resin layers are each thin, the strength of the core substrate is increased by the through-hole conductor. Therefore, a thin electronic component can be built in the core substrate. The thickness of the core substrate is equal to or greater than the thickness of the electronic component. A difference between the thickness of the core substrate and the thickness of the electronic component is in a range from 0 to 220 μm.

As illustrated in FIG. 1, an upper side build-up layer is formed on the first surface (F) of the multilayer core substrate 30 and on the chip capacitor. The upper side build-up layer includes an insulating layer (first interlayer resin insulating layer) (50F) that is formed on the first surface (F) of the multilayer core substrate 30 and on the chip capacitor 110, a conductor layer (upper side conductor layer) (58F) on the insulating layer (50F), and via conductors (60F) that penetrate through the insulating layer (50F) and connect the first conductor layer (34F) or the through-hole conductors and the conductor layer (58F). The via conductors (60F) include via conductors (60FI) that connect the conductor layer (58F) and electrodes (110T) of the electronic component such as the chip capacitor.

A lower side build-up layer is formed on the second surface (S) of the multilayer core substrate 30 and below the chip capacitor. The lower side build-up layer includes an insulating layer (second interlayer resin insulating layer) (50S) that is formed on the second surface (S) of the multilayer core substrate 30 and below the chip capacitor, a conductor layer (lower side conductor layer) (58S) below the insulating layer (50S), and via conductors (60S) that penetrate through the insulating layer (50S) and connect the second conductor layer (34S) or the through-hole conductors and the conductor layer (58S).

A spacing in the opening for accommodating the electronic component is filled with a filler. The spacing is a space between the electronic component and the core substrate. The spacing is filled with a resin component of the interlayer resin insulating layer.

Solder resist layers (70F, 70S) having openings 71 are formed on the upper side and lower side build-up layers. Upper surfaces of the conductor layers (58F, 58S) and the via conductors (60F, 60S) that are exposed by the openings 71 of the solder resist layers function as pads. On the pads, metal films 72 such as Ni/Pd/Au are formed, and on the metal films, solder bumps (76U, 76S) are formed. Via the solder bumps (76U) that are formed on the upper side build-up layer, an IC chip is mounted on the printed wiring board 10. Via the solder bumps (76S) that are formed on the lower side build-up layer, the printed wiring board is mounted on a motherboard.

In the first embodiment, the chip capacitor 110 is built in the multilayer core substrate 30. Therefore, a distance between the chip capacitor 110 and the mounted IC is short. Therefore, power is instantaneously supplied to the IC chip so that the IC chip is unlikely to malfunction.

### Manufacturing Method of First Embodiment

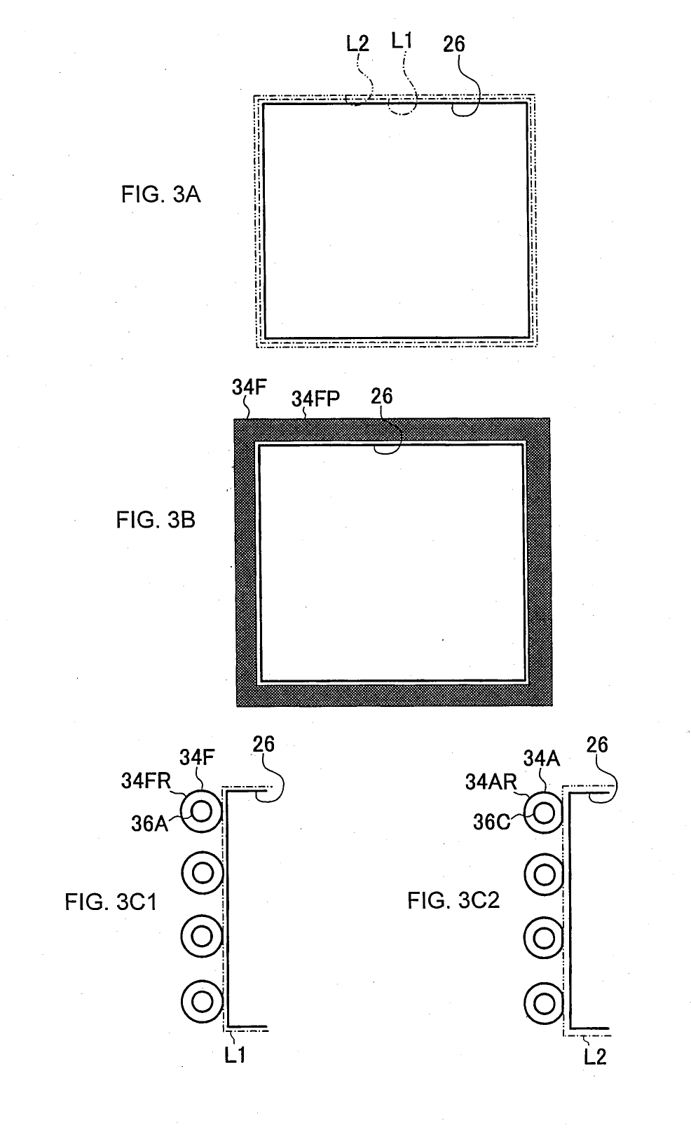

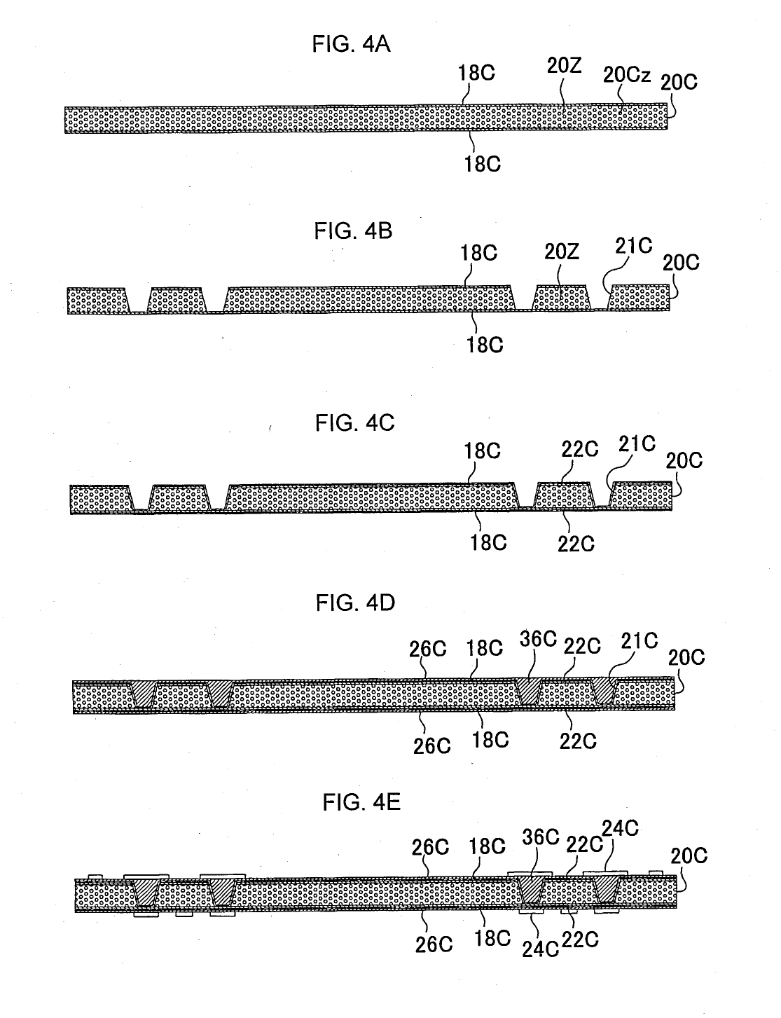

A method for manufacturing the printed wiring board 10 of the first embodiment is illustrated in FIG. 4A-9B.

(1) A double-sided copper-clad laminated plate (20Z), which is formed from an insulating base material (20Cz) having a first surface (F) and a second surface on an opposite side of the first surface (F) and a copper foil (18C) laminated on both sides of the insulating base material (20Cz), is a starting material. The insulating base material has a thickness of 45-75 μm. When the thickness is less than 45 μm, the strength of the substrate is too low. When the thickness exceeds 75 μm, the printed wiring board becomes thick. A surface of the copper foil (18C) is subjected to a blackening treatment (not illustrated in the drawings) (FIG. 4A). The insulating base material includes a glass cloth. The glass is a T glass. The insulating base material (20Cz) corresponds to the third resin layer (20C).

(2) Laser is irradiated to the double-sided copper-clad laminated plate (20Z) from the first surface (F) side of the insulating base material. Openings (21C) for via conductors are formed in the insulating base material (FIG. 4B).

(3) By an electroless plating treatment, an electroless plating film (22C) is formed on inner walls of the openings (21C) and on the copper foil (FIG. 4C).

(4) By an electrolytic plating treatment, an electrolytic plating film (26C) is formed on the electroless plating film. The openings (21C) are filled by the electrolytic plating film and the via conductors (36C) are formed. The via conductors (36C) are formed by the electroless plating film (22C) that is formed on the inner walls of the openings (21C) and the electrolytic plating film (26C) that fills the openings (21C) (FIG. 4D).

(5) An etching resist (24C) of a predetermined pattern is formed on the electrolytic plating film (26C) (FIG. 4E).

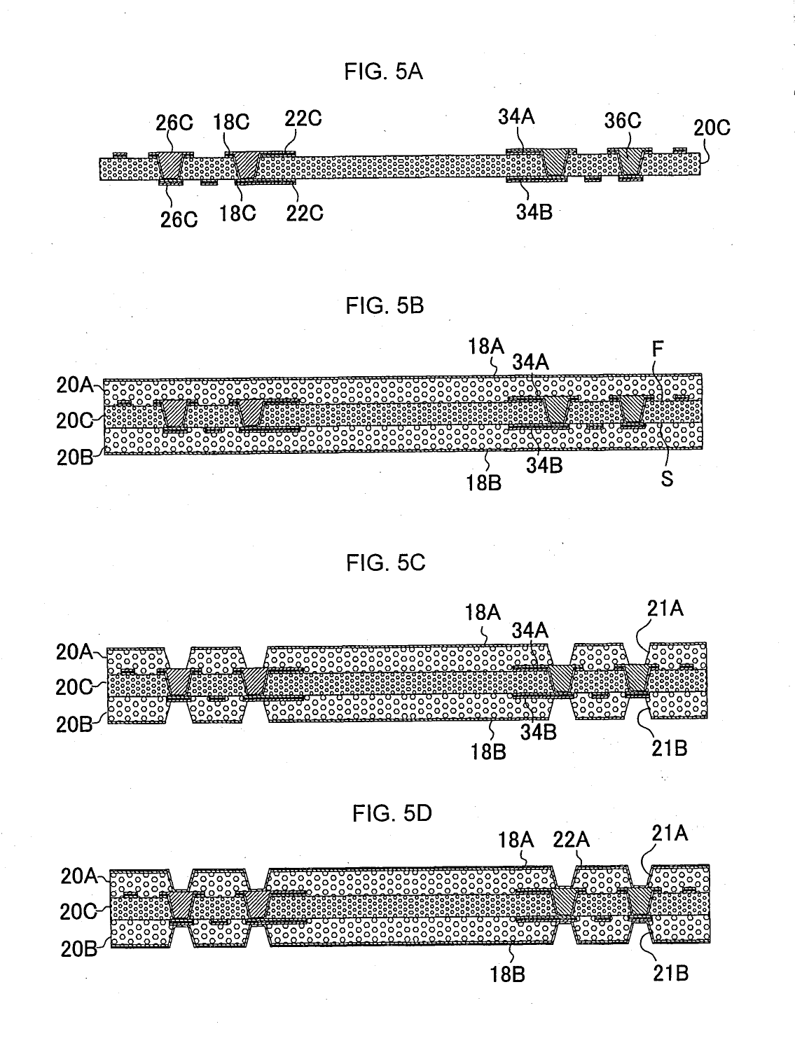

(6) The electrolytic plating film (22C), the electroless plating film (26C) and the copper foil (18C) that are exposed from the etching resist are removed. Thereafter, the etching resist is removed. The third conductor layer (34A), the fourth conductor layer (34B) and the via conductors (36C) are formed (FIG. 5A).

(7) A prepreg and a metal foil (18A) are superposed on the first surface (F) of the third resin layer (20C) and on the third conductor layer (34A). A prepreg and a metal foil (18A) are superposed on the second surface of the third resin layer (20C) and on the fourth conductor layer (34B). Thereafter, by hot pressing, the prepregs and the metal foils (18C) are laminated on the third resin layer (20C). From the prepregs, the first resin layer (20A) and the second resin layer (20B) are formed (FIG. 5B). The first surface of the first resin layer and the second surface of the second resin layer are outermost layers of the core substrate.

(8) Openings (21A) for via conductors that reach the third conductor layer (34A) on the third resin layer are formed using CO2 gas laser from the first surface side of the first resin layer (20A), and openings (21B) for via conductors that reach the fourth conductor layer (34B) on the third resin layer are formed using CO2 gas laser from the second surface side of the second resin layer (20B) (FIG. 5C).

(9) By an electroless plating treatment, an electroless plating films (22A) is formed on inner walls of the openings (21A, 21B) for the via conductors and on the metal foils (18A, 18B) (FIG. 5D).

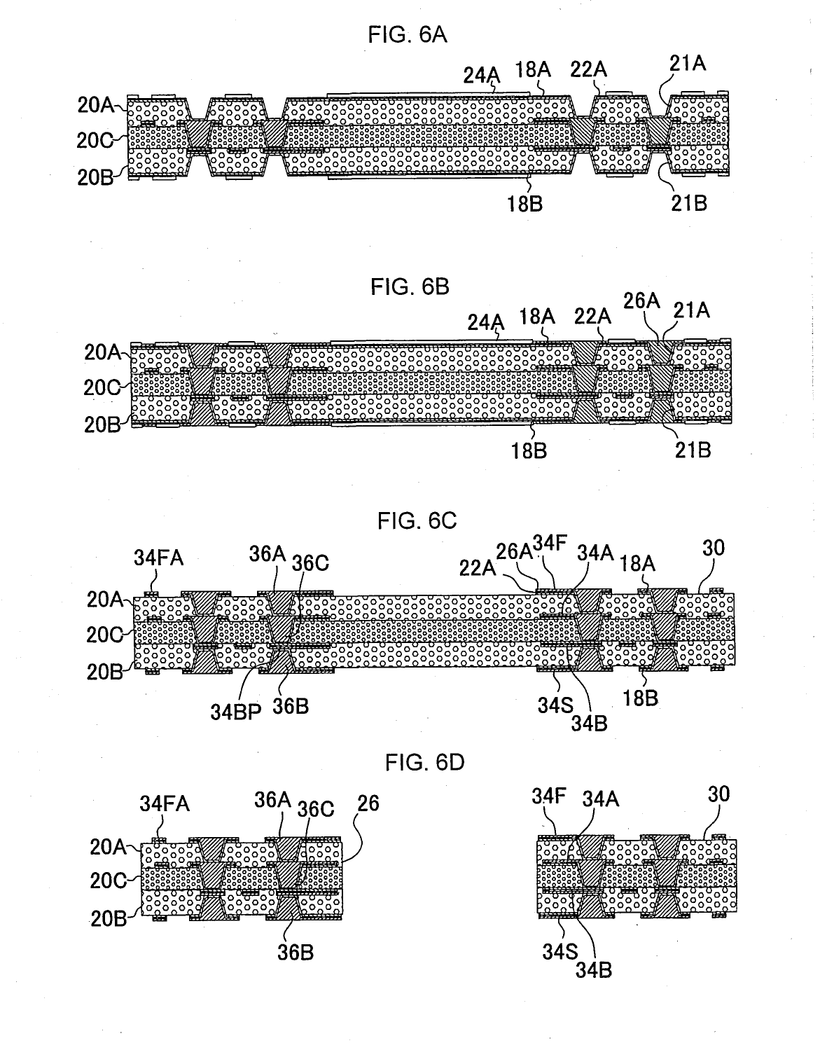

(10) A plating resist (24A) is formed on the electroless plating film (22A) (FIG. 6A).

(11) Next, by an electrolytic plating treatment, an electrolytic plating film (26A) is formed on the electroless plating film (22A) that is exposed from the plating resist (24A) (see FIG. 6B).

(12) Next, the plating resist is removed. Thereafter, the electroless plating film (22A) and the metal foils (18A, 18B) that are exposed from the electrolytic copper plating film (26A) are removed by etching, and the first conductor layer (34F) and the second conductor layer (34S) that are formed from the metal foils (18A, 18B), the electroless plating film (22A) and the electrolytic plating film (26A) are formed. At the same time, the via conductors (36A, 36B) are formed (FIG. 6C).

The first conductor layer (34F) includes the alignment mark (34FA). Further, the first conductor layer (34F) and the second conductor layer (34S) each include multiple conductor circuits and via conductor lands. The fourth conductor layer (34B) includes the via conductor pads (34BP). In addition to the pads, the fourth conductor layer may include a conductor circuit. The pad (34BP) in the fourth conductor layer and the via conductors (36B, 36C) sandwiching the pad are linearly arranged, and function as a through-hole conductor.

(13) The opening 26 that reaches the second surface of the second resin layer (20B) from the first surface of the first resin layer (20A) is positioned using the alignment mark (34FA) in the first conductor layer as a reference and is formed using laser. The opening 26 simultaneously penetrates through the first resin layer, the third resin layer and the second resin layer (FIG. 6D). The multilayer core substrate 30 having the resin layers is completed. The opening 26 may also be tapered from the second surface toward the first surface.

As described above with reference to FIG. 2, the distance from the opening of the multilayer core substrate to each of the inner layer conductor patterns (34A, 34B) is greater than the distance from the opening to each of the outer layer conductor patterns (34F, 34S). Therefore, when the opening is formed in the multilayer core substrate using laser using the alignment mark (34FA) of the outer layer conductor pattern (34F) as a reference, the inner layer conductor patterns (34A, 34B) are avoided from being hit by the laser. The opening for accommodating the electronic component can be properly formed. Therefore, reliability of the printed wiring board with the built-in electronic component is enhanced.

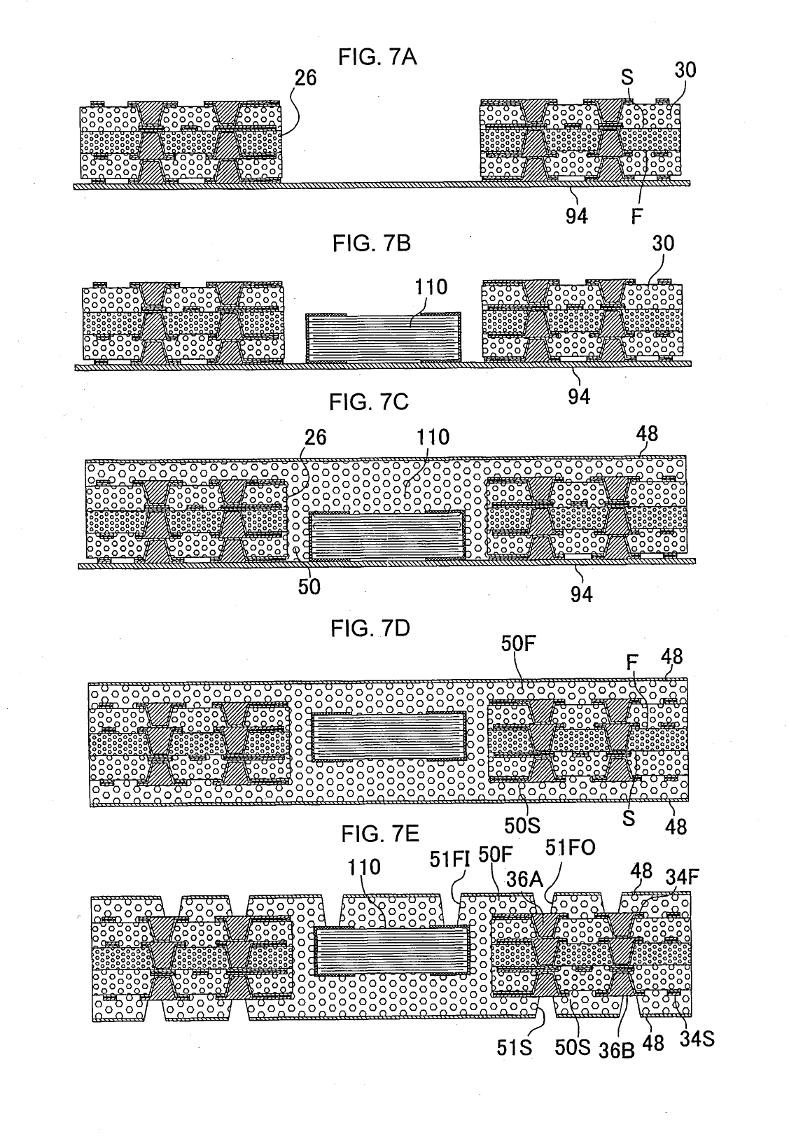

(14) The multilayer core substrate 30 is reversed so that the second surface (S) faces upward and the first surface (F) faces downward. A tape 94 is affixed to the first surface of the multilayer core substrate 30. The opening 26 is closed by the tape (FIG. 7A). An example of the tape 94 is a PET film.

(15) On the tape 94 that is exposed by the opening 26, the chip capacitor 110 is placed (FIG. 7B). The chip capacitor accommodated in the opening 26 of the core substrate has a thickness of 75%-100% of that of the core substrate.

(16) A prepreg of a B-stage and a metal foil 48 are laminated on the second surface of the core substrate and on the electronic component. By hot pressing, resin seeps out from the prepreg into the opening, and the opening 26 is filled with a filler (resin filler) 50 (FIG. 7C). A spacing between an inner wall of the opening and the chip capacitor is filled with the filler. The chip capacitor is fixed in the core substrate. Instead of the prepreg, it is also possible that a resin film for an interlayer insulating layer is laminated. The prepreg has a reinforcing material such as a glass cloth. However, the resin film for an interlayer resin layer does not have a reinforcing material. It is preferable that both the prepreg and the resin film contain inorganic particles such as glass particles. The filler contains inorganic particles such as silica.

(17) After the tape is peeled off, the multilayer core substrate 30 is reversed so that the first surface (F) faces upward and the second surface (S) faces downward. A prepreg of a B-stage and a metal foil 48 are laminated on the first surface of the core substrate and on the electronic component. The prepregs that are laminated on both sides of the core substrate are heated and cured, and the interlayer resin insulating layers (50F, 50S) are formed (FIG. 7D). The interlayer resin insulating layer (50F) belongs to the upper side build-up layer, and the interlayer resin insulating layer (50S) belongs to the lower side build-up layer.

(18) Openings (51FO) for via conductors that reach the first conductor layer (34F) and the via conductors (36A) of the first resin layer are formed in the interlayer resin insulating layer (50F). At the same time, openings (51FI) for via conductors that reach the electrodes (110T) of the electronic component 110 are formed.

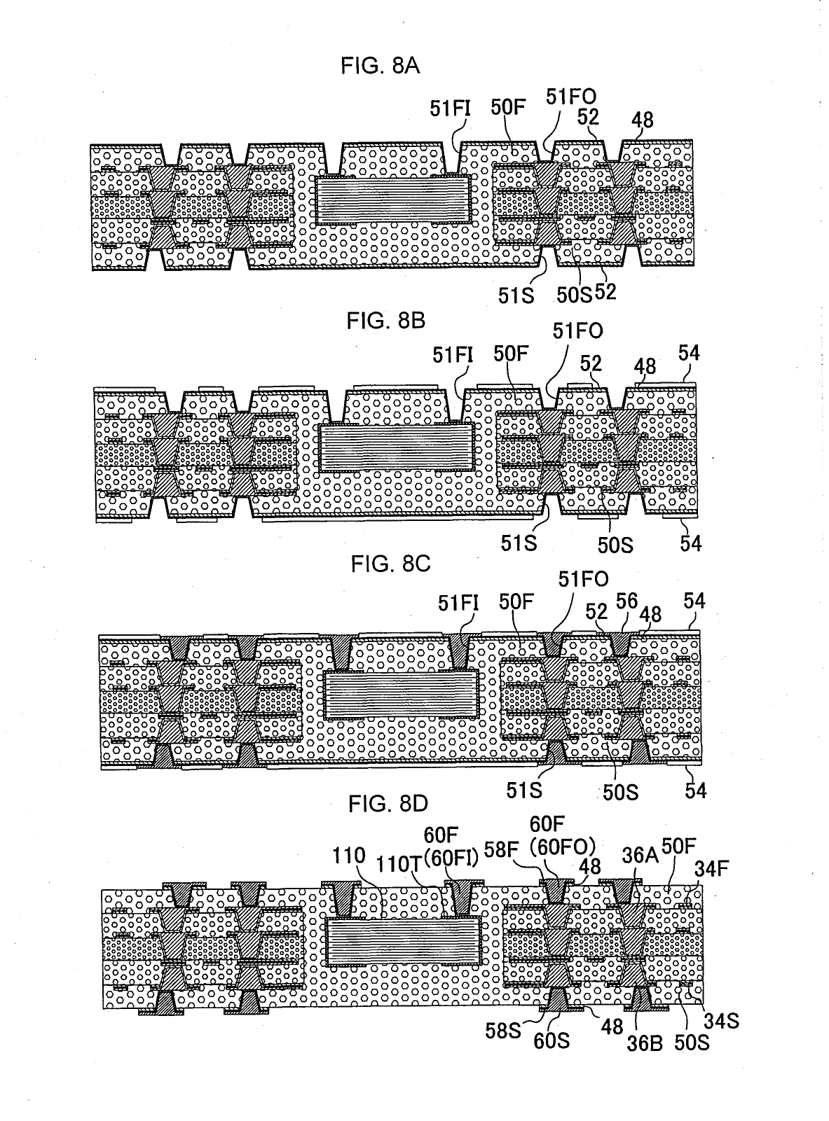

Openings (51S) for via conductors that reach the second conductor layer (34S) and the via conductors (36B) of the second resin layer are formed in the interlayer resin insulating layer (50S). Electroless plating films 52 are formed on the metal foils (48, 48) and on inner walls of the openings (51FO, 51FI, 51S) (FIG. 8A). Thereafter, plating resists (54, 54) are formed on the electroless plating films (FIG. 8B). Next, electrolytic plating films (56, 56) are formed on the electroless plating films that are exposed from the plating resists (54, 54) (FIG. 8C). Then, the plating resists are removed, and the electroless plating films (52, 52) and the metal foils 48, 48 that are exposed from the electrolytic plating films are removed. Build-up layers are completed (FIG. 8D). The one-layer build-up layers are formed by the interlayer resin insulating layers (50F, 50S), the conductor layers (58F, 58S) on the interlayer resin insulating layers, and the via conductors (60FI, 60FO, 60S) that penetrate through the interlayer resin insulating layers. The via conductors (60FO) connect the first conductor layer (34F) and the through-hole conductor (36A) to the conductor layer (58F). The via conductors (60FI) connect the electrodes (110T) of the electronic component 110 to the conductor layer (58F). The via conductors (60S) connect the second conductor layer (34S) and the through-hole conductor (36B) to the conductor layer (58S). The build-up layer on the first surface of the core substrate is the upper side build-up layer, and the build-up layer on the second surface of the core substrate is the lower side build-up layer. The interlayer resin insulating layers (50F, 50S) each have a reinforcing material such as a glass cloth.

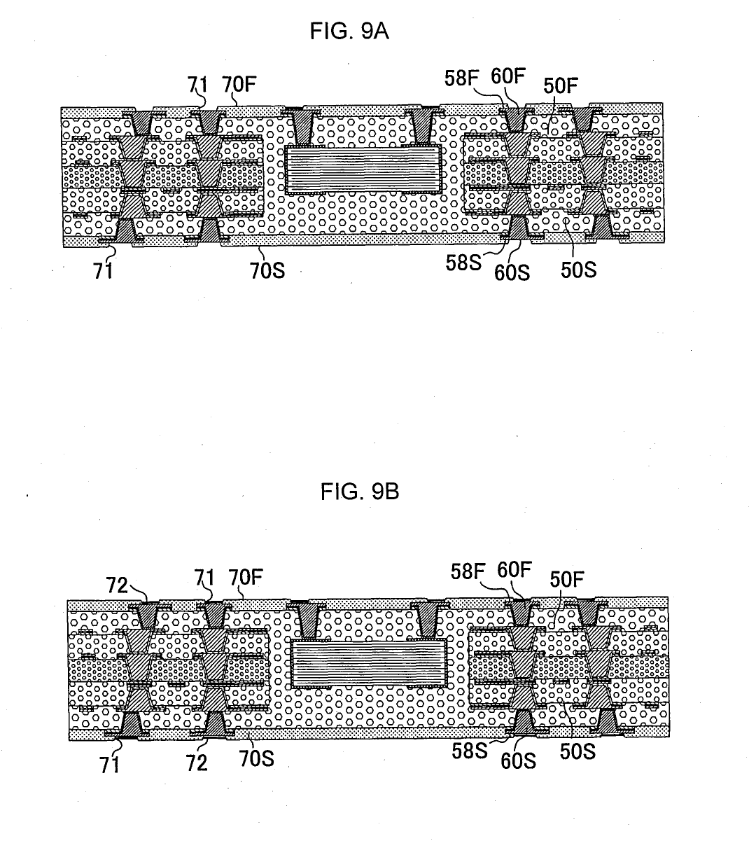

(19) The solder resist layers (70F, 70S) having the openings 71 are formed on the upper side and lower side build-up layers (FIG. 9A). The openings 71 expose upper surfaces of the conductor layers and the via conductors. The exposed portions function as pads.

(20) On each of the pads, a metal film 72 is formed that includes a nickel layer and a gold layer on the nickel layer (FIG. 9B). Other than the nickel-gold layers, a metal film formed from nickel-palladium-gold layers may also be adopted. In the printed wiring board illustrated in FIG. 1, only the upper side build-up layer has connection via conductors. The connection via conductors are the via conductors that connect to the electrodes of the electronic component. Therefore, it is also possible that the lower side build-up layer does not have a conductor circuit on the lower side of the electronic component such as the chip capacitor. When the lower side build-up layer directly below the chip capacitor does not have a conductor circuit, warpage is likely to occur in the printed wiring board. In this case, it is preferable that the insulating layer of the upper side build-up layer have a thickness greater than that of the lower side build-up layer.

(21) Thereafter, the solder bumps (76U) are formed on the pads of the upper side build-up layer and the solder bumps (76S) are formed on the pads of the lower side build-up layer. The printed wiring board 10 having the solder bumps is completed (FIG. 1).

Via the solder bumps (76U), an IC chip (not illustrated in the drawings) is mounted on the printed wiring board 10. Thereafter, via the solder bumps (76S), the printed wiring board is mounted on a motherboard.

### Modified Example of First Embodiment

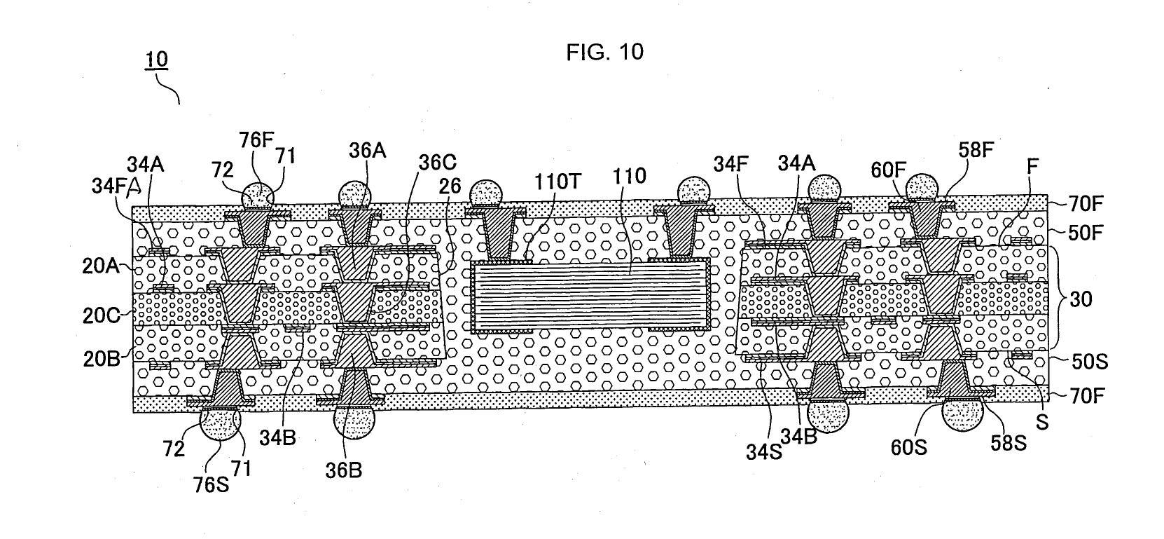

FIG. 10 illustrates a cross section of a printed wiring board according to a modified example of the first embodiment.

In the modified example of the first embodiment, the opening 26 is tapered from the first surface side of the multilayer core substrate toward the second surface side. Also in such a shape of the opening, by arranging each of the inner layer conductor patterns to be more distanced from the opening than each of the outer layer conductor patterns is, the reliability of the opening can be enhanced.

A multilayer core substrate having a conductor pattern in an inner layer may be used as a core substrate of a printed wiring board. In the case of such a multilayer core substrate, there is a problem that, when an opening for accommodating a chip capacitor is formed using laser, the inner layer conductor pattern is hit by the laser so that the opening is not properly formed and thus reliability of the printed wiring board is reduced by having the chip capacitor built in such an opening.

A printed wiring board with a built-in electronic component according to an embodiment of the present invention enhances its reliability.

A printed wiring board according to an embodiment of the present invention includes: a multilayer core substrate that is formed by multiple resin layers that include a via conductor, includes inner layer conductor patterns that are formed on an inner layer of the resin layers and outer layer conductor patterns that are formed on outer layers of the resin layers, and has an opening for accommodating an electronic component; the electronic component that is accommodated in the opening of the multilayer core substrate; and a build-up layer that includes an interlayer resin insulating layer that is formed on the multilayer core substrate and covers the opening. A distance from the opening to each of the inner layer conductor patterns is greater than a distance from the opening to each of the outer layer conductor patterns.

A method for manufacturing a printed wiring board according to another embodiment of the present invention includes: forming a multilayer core substrate that includes multiple resin layers, a via conductor penetrating through the resin layers, inner layer conductor patterns that are formed on an inner layer of the resin layers, and outer layer conductor patterns that are formed on outer layers of the resin layers, the inner layer conductor patterns being formed such that a distance from an opening formation position to each of the inner layer conductor patterns is greater than a distanced from the opening formation position to each of the outer layer conductor patterns; forming an opening in the multilayer core substrate using laser using an alignment mark on the outer layer conductor patterns as a reference; accommodating an electronic component in the opening; and forming a build-up layer on the multilayer core substrate.

In a printed wiring board according to an embodiment of the present invention and a method for manufacturing a printed wiring board according to an embodiment of the present invention, the distance from the opening to each of the inner layer conductor patterns is greater than the distance from the opening to each of the outer layer conductor patterns. Therefore, when the opening is formed in the multilayer core substrate using laser using the alignment mark of the outer layer conductor patterns as a reference, the inner layer conductor patterns are avoided from being hit by the laser. The opening for accommodating the electronic component can be properly formed. Therefore, reliability of the printed wiring board with the built-in electronic component is enhanced.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a multilayer core substrate;
an electronic component accommodated in an opening portion formed in the multilayer core substrate; and
a build-up layer comprising an interlayer resin insulating layer formed on the multilayer core substrate such that the interlayer resin insulating layer is covering the opening portion of the multilayer core substrate,
wherein the multilayer core substrate comprises a plurality of resin layers, a plurality of inner layer conductor patterns formed on an inner layer of the plurality of resin layers and a plurality of outer layer conductor patterns formed on an outer layer of the plurality of resin layers, and a plurality of via conductors formed in the resin layers, and the multilayer core substrate is formed such that a distance from the opening portion to each of the inner layer conductor patterns is greater than a distance from the opening portion to each of the outer layer conductor patterns.

2. A printed wiring board according to claim 1, wherein the multilayer core substrate is formed such that the distance from the opening portion to each of the inner layer conductor patterns is greater than the distance from the opening portion to each of the outer layer conductor patterns by 20 μm or more.

3. A printed wiring board according to claim 1, wherein the plurality of outer layer conductor patterns includes a plane layer having a frame shape surrounding a periphery of the opening portion.

4. A printed wiring board according to claim 1, wherein each of the inner layer conductor patterns comprises a via land portion of a stacked via conductor structure comprising the plurality of via conductors, each of the outer layer conductor patterns comprises a via land portion of the stacked via conductor structure, and the via land portion has a cut-off portion formed along the opening portion.

5. A printed wiring board according to claim 1, wherein the opening portion of the multilayer substrate has a continuous cut-surface formed through the plurality of resin layers.

6. A printed wiring board according to claim 1, wherein the opening portion of the multilayer substrate has a tapered wall formed through the plurality of resin layers.

7. A printed wiring board according to claim 2, wherein the plurality of outer layer conductor patterns includes a plane layer having a frame shape surrounding a periphery of the opening portion.

8. A printed wiring board according to claim 2, wherein each of the inner layer conductor patterns comprises a via land portion of a stacked via conductor structure comprising the plurality of via conductors, each of the outer layer conductor patterns comprises a via land portion of the stacked via conductor structure, and the via land portion has a cut-off portion formed along the opening portion.

9. A printed wiring board according to claim 2, wherein the opening portion of the multilayer substrate has a continuous cut-surface formed through the plurality of resin layers.

10. A printed wiring board according to claim 2, wherein the opening portion of the multilayer substrate has a tapered wall formed through the plurality of resin layers.

11. A printed wiring board according to claim 1, wherein the outer layer of the plurality of the resin layers is formed in a plurality such that the inner layer is formed between the plurality of outer layers.

12. A printed wiring board according to claim 11, wherein the multilayer core substrate is formed such that the distance from the opening portion to each of the inner layer conductor patterns is greater than the distance from the opening portion to each of the outer layer conductor patterns by 20 μm or more.

13. A printed wiring board according to claim 11, wherein the plurality of outer layer conductor patterns includes a plane layer having a frame shape surrounding a periphery of the opening portion.

14. A printed wiring board according to claim 11, wherein each of the inner layer conductor patterns comprises a via land portion of a stacked via conductor structure comprising the plurality of via conductors, each of the outer layer conductor patterns comprises a via land portion of the stacked via conductor structure, and the via land portion has a cut-off portion formed along the opening portion.

15. A printed wiring board according to claim 1, wherein each of the inner layer conductor patterns comprises a via land portion of a stacked via conductor structure comprising the plurality of via conductors, and each of the outer layer conductor patterns comprises a via land portion of the stacked via conductor structure.

16. A method for manufacturing a printed wiring board, comprising:
forming a multilayer core substrate comprising a plurality of outer layer conductor patterns including an alignment mark;
applying laser upon the multilayer core substrate using the alignment mark as a reference such that an opening portion is formed at an opening formation position of the multilayer core substrate;
accommodating an electronic component in the opening portion of the multilayer core substrate; and
forming a build-up layer comprising an interlayer resin insulating layer on the multilayer core substrate such that the interlayer resin insulating layer covers the opening portion of the multilayer core substrate,
wherein the forming of the multilayer core substrate includes laminating a plurality of resin layers, forming a plurality of via conductors in the resin layers, forming a plurality of inner layer conductor patterns on an inner layer of the resin layers, and forming a plurality of outer layer conductor patterns on an outer layer of the resin layers, and the inner layer conductor patterns and the outer layer conductor patterns are formed such that a distance from the opening formation position to each of the inner layer conductor patterns is greater than a distanced from the opening formation position to each of the outer layer conductor patterns.

17. A method for manufacturing a printed wiring board according to claim 16, wherein the inner layer conductor patterns and the outer layer conductor patterns are formed such that the distance from the opening portion to each of the inner layer conductor patterns is greater than the distance from the opening portion to each of the outer layer conductor patterns by 20 μm or more.

18. A method for manufacturing a printed wiring board according to claim 1, wherein the forming of the outer layer conductor patterns includes forming a plane layer having a frame shape surrounding a periphery of the opening portion.

19. A method for manufacturing a printed wiring board according to claim 1, wherein each of the inner layer conductor patterns comprises a via land portion of a stacked via conductor structure comprising the plurality of via conductors, each of the outer layer conductor patterns comprises a via land portion of the stacked via conductor structure, and the via land portion has a cut-off portion formed along the opening portion.

20. A method for manufacturing a printed wiring board according to claim 1, wherein each of the inner layer conductor patterns comprises a via land portion of a stacked via conductor structure comprising the plurality of via conductors, and each of the outer layer conductor patterns comprises a via land portion of the stacked via conductor structure.
